(19) United States
(12) Patent Application Publication
(10) Pub. No.: US 2002/0050405 A1
(43) Pub. Date: May 2, 2002

(54) Multilayer printed wiring board, method of producing same, mounting substrate and electronics

(76) Inventor: Motoo Yamaguchi, Hitachi (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/791,673

(22) Filed: Feb. 26, 2001

(30) Foreign Application Priority Data
Nov. 2, 2000 (JP) 2000-336339

(51) Int. Cl. H05K 1/16

(52) U.S. Cl. 174/260

(57) ABSTRACT

A multilayer printed wiring board is provided which comprises an insulation layer containing fillers and which ensures an insulation service life of a long period of time without losing electric insulation even in a case of such a very small underlayer-circuit-conductor spacing as to be not more than 100 μm. The multilayer printed wiring board comprises insulation resin portions containing no filler each of which portions is located between adjacent underlayer circuit conductors located on a base insulation substrate and each of which portions has a height higher than that of each of the underlayer circuit conductors.

### BACKGROUND OF THE INVENTION

The invention relates to a multilayer printed wiring board having internal layer circuit conductors, and particularly to a multilayer printed wiring board preferably used in a case where it is necessary to provide fine pitch patterns for the high density wiring of electronics such as portable telephones etc., game machines, and video cameras etc.

In recent years, for realizing the thin thickness design and high density design of a multilayer interconnection board, there is used a build-up process. An example of the sectional structure of a conventional multilayer printed wiring board produced by the build-up process is shown in FIG. 5, which is a representative constitution disclosed in JP-A-7-224252. As shown in the schematic sectional view of FIG. 5, the conventional multilayer interconnection board has been produced by a method comprising the steps of: forming conductors of internal layer, that is, underlayer circuit conductors 2a and 2b on the surface of a base insulation substrate; locating a film-shaped insulation resin prepreg containing fillers; heating and pressurizing the prepreg to thereby form a fillers-containing insulation layer 4; and forming upper layer circuit conductors 5a and 5b on the outer face of the insulation layer 4.

The structure shown in FIG. 5 makes it possible to realize a very small layer-to-layer spacing not more than 100 μm between the underlayer circuit conductors 2a and 2b and the upper layer circuit conductors 5a and 5b, and makes the thermal expansion coefficient of the multilayer printed wiring board approach the thermal expansion coefficient of a package by the mixing of the fillers, whereby the peeling-off of solder can be prevented from being caused due to difference in thermal expansion coefficient at the time of mounting the package. That is, the structure shown in FIG. 5 is means effective to produce the multilayer printed wiring board.

### SUMMARY OF THE INVENTION

However, the inventor of the invention has found such a problem as, in the multilayer printed wiring board in which the insulation layer containing the fillers is used, the insulation reliability thereof is lowered with the result that the insulation service life thereof becomes short.

An object of the invention is to solve the problem, that is, to obtain a multilayer printed wiring board having an insulation layer containing fillers which board can ensure insulation service life in a long period of time without losing electric insulation ability regarding very small underlayer circuit conductor spacing not more than 100 μm.

Another object of the invention is to obtain a method of producing the multilayer printed wiring board having the insulation layer containing the fillers which board can ensure prolonged insulation service life.

Still another object of the invention is to obtain a mounting substrate and electronics, each of which is provided with the multilayer printed wiring board ensuring the prolonged insulation service life.

The inventor searched the insulation deterioration occurring in the conventional multilayer printed wiring board in which the insulation layer containing the fillers is used, and found the fact disclosed below. FIG. 6 is an enlarged, schematic sectional view of the underlayer circuit conductor portion of the multilayer printed wiring board having the insulation layer containing the fillers. In the conventional method in which the fillers-containing insulation layer is formed between the underlayer circuit conductors 2a and 2b by pressurizing and heating-and-curing, the fillers-containing insulation layer is deformed and forced into spaces 4a each defined between the underlayer circuit conductors 2a and 2b. As the result thereof, a part of the fillers 6 is made to be located in the space 4a while contacting with the edge portions 11a and 11b of the underlayer circuit conductors 2a and 2b. The amount of the fillers contained in the insulation layer is usually 50 vol. % or more to make the thermal expansion coefficient of the resin of the insulation layer approach the thermal expansion coefficient of a package to be mounted, so that it is difficult to prevent defect portions from occurring in the fillers-containing insulation layer in which defect portions the fillers itself is condensed and is in contact with each other.

In a case where the condensing of the fillers occurs at the edge portions 11a and 11b of the underlayer circuit conductors 2a and 2b or at portions under the edge portions 11a and 11b, bridging between the underlayer circuit conductors 2a and 2b occurs through the fillers 6. Further, there occurs a phenomenon called migration along the fillers 6 between the underlayer circuit conductors 2a and 2b, the dissolving and precipitating of copper of electrode of one side being repeated therebetween, with the results that electrical continuity is caused between underlayer circuit conductors 2a and 2b due to precipitated copper and that the electric insulation is lost, so that it becomes impossible to transmit accurate signals insofar as the underlayer circuit conductors 2a and 2b are concerned. Particularly, in a case of a very small conductor spacing not more than 100 μm between underlayer circuit conductors 2a and 2b, this unfavorable phenomenon becomes remarkable due to the increase in the number of the defects of the bridging caused by the condensed fillers.

The invention is completed on the basis of the research regarding the insulation deterioration explained above.

According to the first aspect of the invention, there is provided, as shown in FIG. 1, a multilayer printed wiring board comprises underlayer circuit conductors (2a, 2b), upper-layer circuit conductors (5a, 5b), and an insulation resin layer (4) including fillers located between the underlayer and upper-layer circuit conductors, wherein spaces each defined between the adjacent underlayer circuit conductors are filled with insulation resin portions containing no filler, and a height of each of the underlayer circuit conductors is lower than that of each of the insulation resin portions (3a, 3b and 3c) containing no filler. The underlayer circuit conductors (2a, 2b) may be formed by etching a copper foil bonded onto the base insulation substrate.

According to the second aspect of the invention, there is provided a multilayer printed wiring board comprising circuit conductors (2a, 2b), and an insulation resin layer (4) containing fillers which insulation resin layer is located on the circuit conductors, wherein spaces each defined between the circuit conductors adjacent to each other are filled with insulation resin portions (3a, 3b and 3c) each containing no filler, and a height of each of the circuit conductors is lower than that of each of the insulation resin portions (3a, 3b and 3c) containing no filler.

According to the third aspect of the invention, there is provided a method of producing a multilayer printed wiring board by forming upper-layer circuit conductors above underlayer circuit conductors through a layer-insulation resin layer containing fillers, the method comprising the steps of: locating on the underlayer circuit conductors a semi-cured insulation resin film containing no filler; pressurizing, heating and curing the insulation resin film so that spaces each defined between the underlayer circuit conductors adjacent to each other is filled with a semi-cured insulation resin containing no filler; removing excessive insulation resin portions located above the underlayer circuit conductors by abrading the excessive resin portions; making a height of each of the underlayer circuit conductors lower than that of the insulation resin containing no filler which resin fills the space between the adjacent underlayer circuit conductors, by use of soft etching technique; locating above the underlayer circuit conductors and on the insulation resin with no filler another semi-cured insulation resin film containing fillers; and pressurizing, heating and curing another insulation resin film to thereby form a layer-insulation resin layer containing the fillers.

According to the fourth aspect of the invention, there is provided a mounting substrate having a printed wiring board on which electronic parts are mounted, the printed wiring board comprising circuit conductors, an insulation resin layer containing fillers which resin layer is located on the circuit conductors, and insulation resin portions each containing no filler which insulation resin portions fill spaces each defined between the circuit conductors adjacent to each other and each of which insulation resin portions has a height higher than the height of each of the circuit conductors.

FIG. 2 is a drawing for explaining the effect of the invention, which drawing schematically shows the behavior of the fillers existing in the portions near the underlayer circuit conductors 2a and 2b.

By providing between the underlayer circuit conductors (2a, 2b) the insulation resin portions (3a, 3b, 3c) containing no filler and by making the height of the underlayer circuit conductors (2a, 2b) lower than the height of each of the insulation resin portions (3a, 3b, 3c) containing no filler as in the case of the invention, it becomes possible to prevent the fillers 6 in the filler-containing insulation layer 4 (which is located on the underlayer circuit conductors 2a and 2b) from being in contact with the edge portions and other portions of the underlayer circuit conductors 2a and 2b because substantially no deformation of the prepreg occurs during the pressurizing, heating and curing thereof, so that no bridging occurs between the underlayer circuit conductors 2a and 2b. Accordingly, it becomes possible to greatly prolong a period of time until the losing of electrical independence between the underlayer circuit conductors 2a and 2b which losing is caused due to the dissolving of copper from the underlayer circuit conductors 2a and 2b and then precipitating of the copper.

### BRIEF DESCRIPTION OF THE DRAWINGS

FIG. 1 is a schematic sectional view showing one example of the multilayer printed wiring board embodying the invention.

FIG. 2 is a drawing for explaining a phenomenon occurring at the underlayer circuit conductor portions of the multilayer printed wiring board embodying the invention.

FIGS. 3A to 3I are sectional views showing the steps of a method for producing the multilayer printed wiring board embodying the invention.

FIGS. 4A to 4J are sectional views showing the steps of another method for producing the multilayer printed wiring board embodying the invention.

FIG. 5 is a schematic sectional view of a conventional multilayer printed wiring board.

FIG. 6 is a sectional view for explaining the phenomenon occurring at the underlayer circuit conductor portions of the conventional multilayer printed wiring board.

FIG. 7 is a graph comparing the insulation deterioration characteristic of the multilayer printed wiring board of the invention with that of the conventional multilayer printed wiring board.

FIGS. 8A to 8C are schematic views showing the steps of mounting electronic parts.

FIGS. 9A and 9B are perspective views showing components of electronics.

### DETAILED DESCRIPTION OF THE PREFERRED EMBODIMENTS

The preferred embodiments of the invention are described below while referring to the drawings.

Embodiment 1

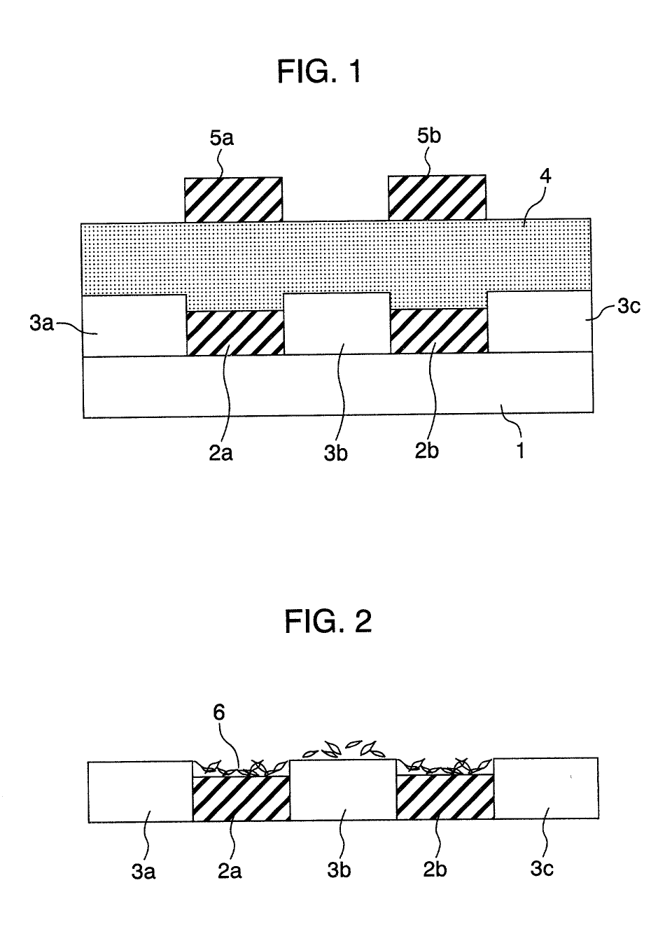

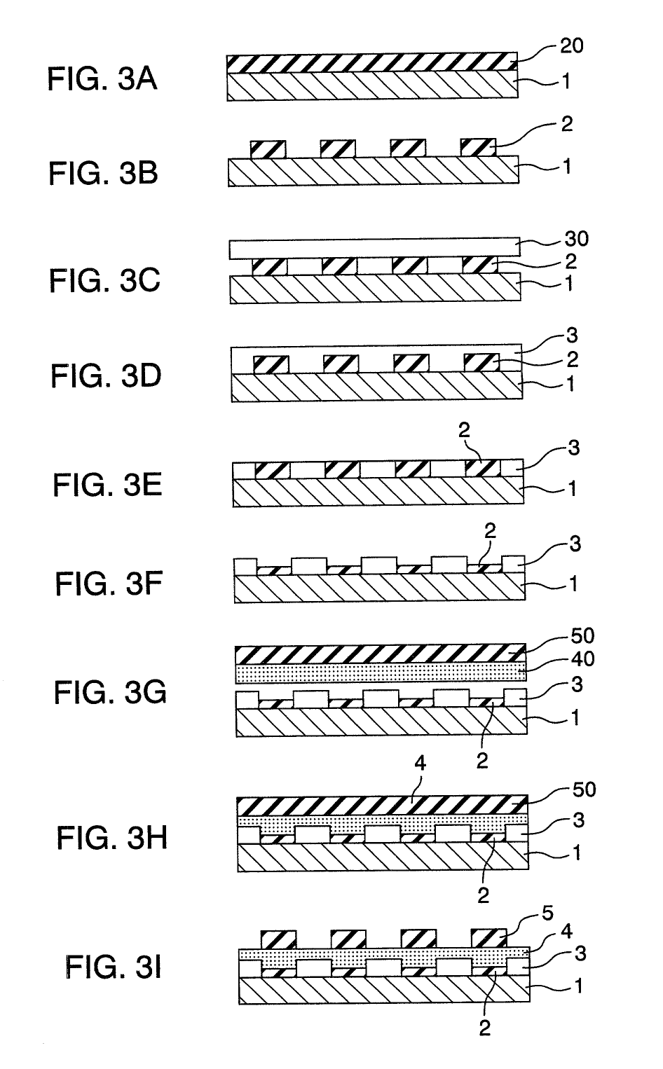

FIG. 1 a schematic sectional view of one example of the multilayer printed wiring board embodying the invention. The steps of the method of producing this multilayer printed wiring board are shown in FIGS. 3A to 3I.

A base insulation substrate 1 shown in FIG. 3A was FR-4 (an insulation substrate produced by impregnating glass cloths with epoxy resin) having a substrate thickness of 0.2 mm and a copper foil 20 of 12 μm in thickness which became underlayer circuit conductors 2. As shown in FIG. 3B, by etching the copper foil 20 located on the substrate 1, the underlayer circuit conductors 2 were formed so that each of the conductor spacing and the conductor width became 75 μm. Then, as shown in FIG. 3C, a semi-cured insulation film 30 of 30 μm in thickness containing no filler was located on the underlayer circuit conductors 2 shown in FIG. 3B. The semi-cured insulation resin film 30 was then pressurized, heated and cured to thereby fill spaces each defined between adjacent underlayer conductors, as shown in FIG. 3D. Next, as shown in FIG. 3E, an excessive portion of the insulation resin 3 which portion was laid in a level higher than that of the underlayer circuit conductors 2 was removed by buffing. In this state, a part of each of the underlayer circuit conductors extended upward from the insulation resin 3. In order to remove the extended portion of each of the underlayer circuit conductors 2, the soft etching of the underlayer circuit conductors 2 was performed as shown in FIG. 3F, so that the height of the surface of the underlayer circuit conductors was made to be lower than that of the insulation resin 3 containing no filler. The amount of the removing thereof by the soft etching was such an amount of about 1 to 2 μm as the underlayer circuit conductor portions extended from the surface of the insulation resin 3 was made to be sufficiently lower than the surface of the insulation resin 3.

Then, an insulation resin layer 4 containing fillers was formed which was a primary build-up layer. In the step of FIG. 3G, there was used a copper foil 50 of 12 μm in thickness which was bonded to an insulation resin sheet 40 of 70 μm in thickness containing fillers, however, both of the copper foil 50 and the insulation resin 40 containing the fillers may be individually layered independently. Then, as shown in FIG. 3H, these were pressurized, heated and cured. Next, the upper layer copper foil 50 was etched to form the upper layer circuit conductors 5, whereby a multilayer printed wiring board shown in FIG. 3I according to the first embodiment was completed.

This embodiment is effective to form the multilayer printed wiring board in which each of the conductor width and the conductor spacing is not less than 50 μm. In FIGS. 3A to 3I, an example for producing the two-layer printed wiring board, however, a three or more-layer printed wiring board may be produced by repeating the steps of FIGS. 3A to 3I predetermined times.

Embodiment 2

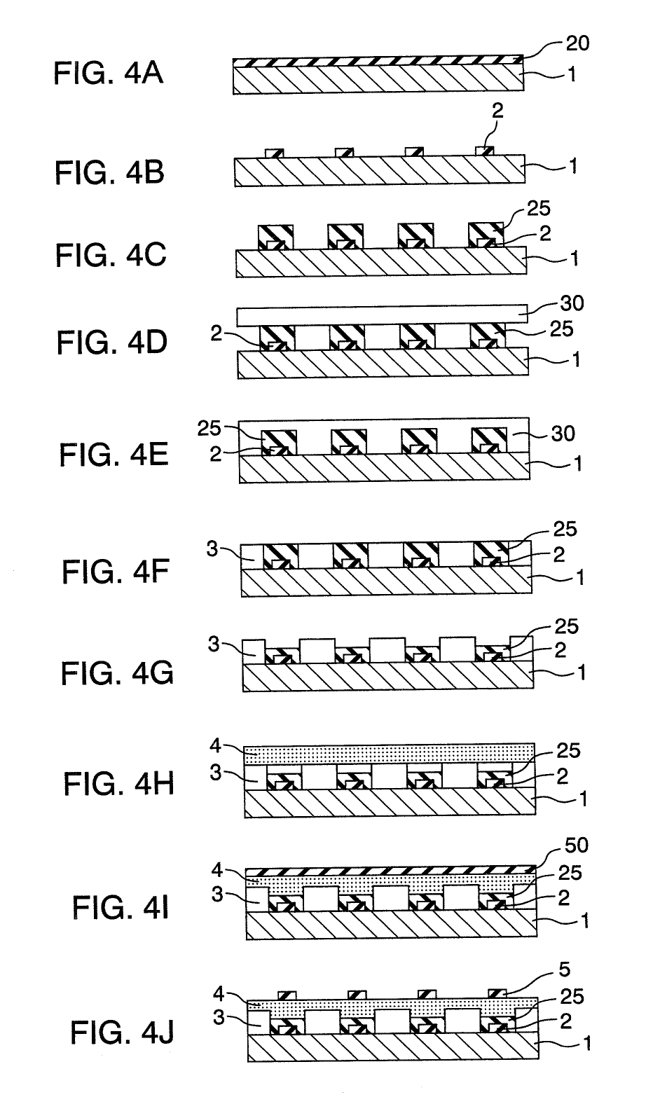

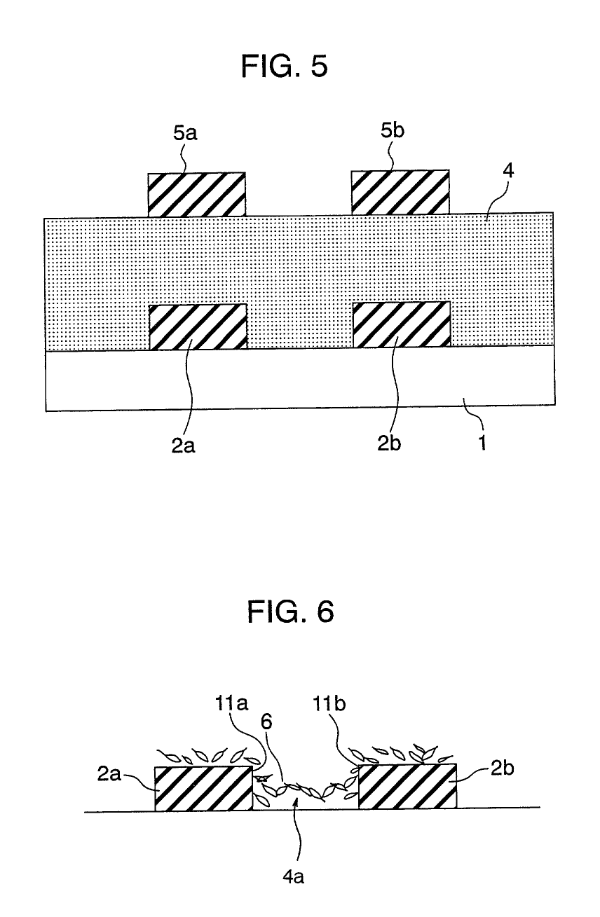

In this embodiment was described an example in which the invention is applied to a multilayer printed wiring board having a very small conductor spacing less than 50 μm. FIGS. 4A to 4J are drawings explaining the production steps thereof.

In FIG. 4A is shown FR-4 (which is an insulation substrate formed by impregnating glass cloths with epoxy resin) having a base substrate 1 of 0.2 mm in thickness and a copper foil of 5 μm in thickness bonded to the base substrate from which copper foil are formed underlayer circuit conductors 2. In a case of a wiring board where the signal power capacity thereof is small, it is possible to produce a multilayer printed circuit board by use of the FR-4 through the steps shown in FIGS. 3A to 3I. Further, the structure shown in FIG. 4A may be formed by either a method of bonding the copper foil or the plating of copper, and any one of these may be used.

By etching the copper foil 20 of this FR-4 was formed the underlayer circuit conductors 2 so that the conductor width and the conductor spacing were 20 μm and 40 μm, respectively, as shown in FIG. 4B. In this step of FIG. 4B, the values of the conductor width and the conductor spacing both formed by the etching need to be selected while taking into account the ratio of another conductor width to another conductor spacing both defined by the conditions of plating at the finish of the plating performed in the next plating step. Then, the plating was performed until the thickness (height) of the underlayer circuit conductors 2 became 10 μm, whereby the conductors were finished to have a conductor width of 30 μm and a conductor spacing of 30 μm as shown in FIG. 4C.

On the underlayer circuit conductors 2 thus formed was located a semi-cured insulation resin film 30 of 30 μm in thickness, as shown in FIG. 4D. Then, the insulation film 30 containing no filler was pressurized, heated and cured to fill spaces each defined between the adjacent underlayer circuit conductors 2 covered with plated copper 25, as shown in FIG. 4E, Next, as shown in FIG. 4F, excessive portions of the no-filler containing insulation resin 3 covering the underlayer circuit conductors 2 coated with the plated copper 25 were removed by buffing. In this state, a part of each of the plated copper portions 25 was extended upward from the surface of the insulation resin 3. In order to remove the extended portions, the soft etching of the underlayer circuit conductors 2 was performed as shown in FIG. 4G, so that each of the underlayer circuit conductors 2 was made to have a height lower than the height of the insulation resin 3. The amount of the removing performed by the soft etching was such a height of 1 to 2 μm as no portion extended above the level of the surface of the insulation resin exists regarding each of the underlayer circuit conductors 2.

Then, as shown in FIG. 4H, another insulation resin film 4 of 50 μm in thickness containing fillers was located on the insulation resin layer 3. In this case, it is possible to locate at the same time a copper foil 50 for forming upper layer circuit conductors 5. In this embodiment is used a method in which the upper layer copper foil 50 is formed, as shown in FIG. 4I, by plating (shown in FIG. 4I) after forming a build-up layer 4 through the pressurizing, heating and curing of the filler-containing insulation layer 4 (shown in FIG. 4H). Next, by etching a copper foil 50, the upper layer circuit conductors 5 were formed, whereby the multilayer printed wiring board shown in FIG. 4J was completed. The conductor thickness of the upper layer circuit conductors 5 may be adjusted as occasion demands.

Comparison Example

For comparison, there was producted a conventional type multilayer printed wiring board was produced by directly forming, without forming any no-filler-containing insulation resin layer 3 provided in the embodiment of FIGS. 3A to 3I, a filler-containing insulation layer 4 in the spaces each defined between the adjacent underlayer circuit conductors 2. The width of underlayer circuit conductors, a conductor spacing, the thickness of each layer and other treatment conditions with respect to the comparison example were the same as those of the embodiment 1.

In order to confirm the effect of the invention, an accelerated insulation-deterioration test of the conventional multlayer printed wiring board thus produced was performed under such test conditions as the accelerated deterioration was performed at a temperature of 85° C. under a humidity of 85% at a voltage of 100 V, and a period of time until the insulation resistance was lowered down to 1 MΩ was judged to be the service life thereof.

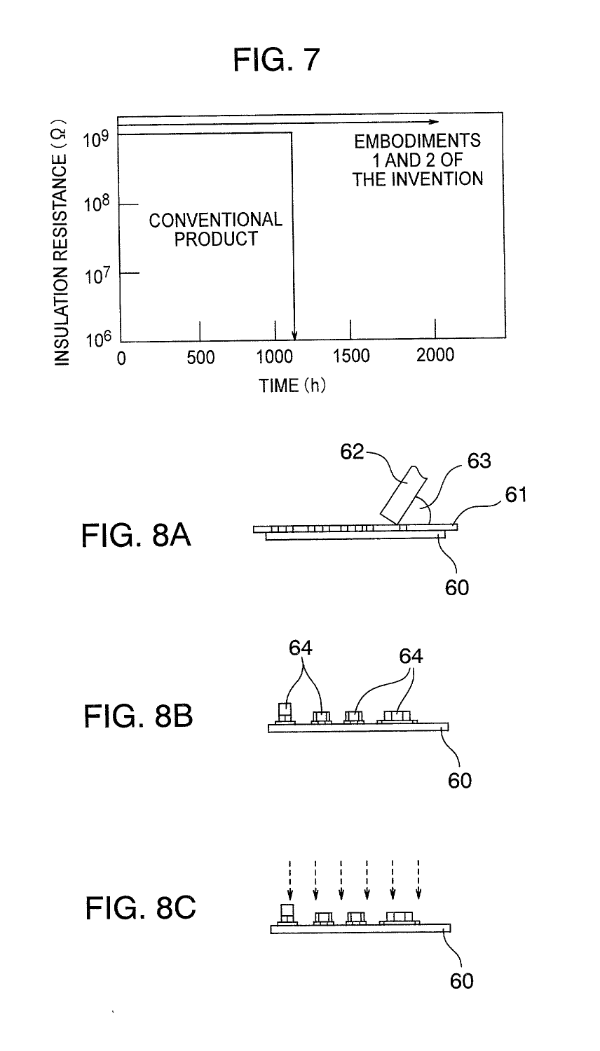

The results of the insulation deterioration test regarding each of the embodiments 1 and 2 and the comparison example are shown in FIG. 7. The comparison example produced by the conventional method terminates the service life when 100 hours has elapsed, however, in each of the samples in the embodiments 1 and 2 there occurs no termination of service life even after the elapse of 2000 hours.

Embodiment 3

By connecting an IC package and chip parts to the multilayer printed wiring board produced in Embodiment 1 was produced a mounting substrate. Further, by use of the mounting substrate, electronics were produced.

FIG. 8 a schematic view explaining the mounting steps thereof. The mounting steps comprise a cream solder-printing step shown in FIG. 8A, a parts-mounting step of FIG. 8B, and a reflow soldering step of FIG. 8C. In the cream solder-printing step, a metal mask 61 was located on land portions which were soldering connection portions provided in the printed wiring board 60, and solder paste 63 was printed by forcing the solder paste 63 through a squeegee 62 into openings formed in the metal mask. In the parts-mounting step, predetermined electronic parts 64 were mounted by a robot onto programmed, predetermined locations, that is, onto the cream solder portions printed on the printed wiring board. At the final step, the printed wiring board on which the parts are mounted was transferred on a conveyor moving in a hot blast stove, so that it was heated at a temperature more than the melting point of the solder, whereby the mounting substrate was produced by use of the multilayer printed wiring board.

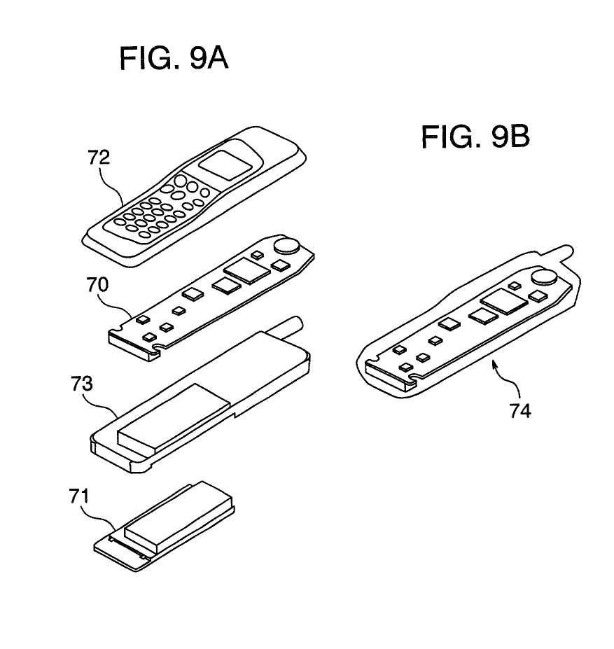

Next, as schematically shown in FIGS. 9A and 9B, another part 71 such as an electric cell and etc. were connected to the mounting substrate 70 to which the electronic parts were connected, and an upper case 72 and a lower case 73 etc. being combined therewith, whereby an electronic device (portable telephone) 74 shown in FIG. 9B was produced. By using the multilayer printed wiring board embodying the invention, it became possible to make an electronic device small in size.

According to the multilayer printed wiring board embodying the invention, it becomes possible to prolong the service life thereof without losing electric insulation among inner layer circuit conductors for a long period of time even if the conductor spacing thereof becomes such a very small value as to be not more than 100 μm.

What is claimed is:

1. A multilayer printed wiring board comprises underlayer circuit conductors, upper-layer circuit conductors, and an insulation resin layer including fillers located between the underlayer and upper-layer circuit conductors, wherein spaces each defined between the adjacent underlayer circuit conductors are filled with insulation resin portions containing no filler, and a height of each of the underlayer circuit conductors is lower than that of each of the insulation resin portions containing no filler.

2. A multilayer printed wiring board comprising circuit conductors, and an insulation resin layer containing fillers which insulation resin layer is located on the circuit conductors, wherein spaces each defined between the circuit conductors adjacent to each other are filled with insulation resin portions each containing no filler, and a height of each of the circuit conductors is lower than that of each of the insulation resin portions containing no filler.

3. A method of producing a multilayer printed wiring board by forming upper-layer circuit conductors above underlayer circuit conductors through a layer-insulation resin layer containing fillers, the method comprising the steps of: locating on the underlayer circuit conductors a semi-cured insulation resin film containing no filler; pressurizing, heating and curing the insulation resin film so that spaces each defined between the underlayer circuit conductors adjacent to each other is filled with a semi-cured insulation resin containing no filler; removing excessive insulation resin portions located above the underlayer circuit conductors by abrading the excessive resin portions; making a height of each of the underlayer circuit conductors lower than that of the insulation resin containing no filler which resin fills each of the spaces between the adjacent underlayer circuit conductors, by use of soft etching technique; locating above the underlayer circuit conductors and on the insulation resin with no filler another semi-cured insulation resin film containing fillers; and pressurizing, heating and curing said another insulation resin film to thereby form a layer-insulation resin layer containing the fillers.

4. A mounting substrate having a printed wiring board on which electronic parts are mounted, the printed wiring board comprising circuit conductors, an insulation resin layer containing fillers which resin layer is located on the circuit conductors, and insulation resin portions containing no filler which resin portions fill spaces each defined between the circuit conductors adjacent to each other and each of which resin portions has a height higher than the height of each of the circuit conductors.

5. An electronic device comprising a mounting substrate according to claim 4.

6. A multilayer printed wiring board comprises underlayer circuit conductors, upper-layer circuit conductors, and an insulation resin layer including fillers located between the underlayer and upper-layer circuit conductors, wherein spaces each defined between the adjacent underlayer circuit conductors are filled with insulation resin portions, and a height of each of the underlayer circuit conductors is lower than that of each of said insulation resin portions.

7. A multilayer printed wiring board comprising circuit conductors, and an insulation resin layer containing fillers which insulation resin layer is located on the circuit conductors, wherein spaces each defined between the circuit conductors adjacent to each other are filled with insulation resin portions, and a height of each of the circuit conductors is lower than that of each of said insulation resin portions.

8. A method of producing a multilayer printed wiring board by forming upper-layer circuit conductors above underlayer circuit conductors through a layer-insulation resin layer containing fillers, the method comprising the steps of: locating on the underlayer circuit conductors a semi-cured insulation resin film; pressurizing, heating and curing the insulation resin film so that spaces each defined between the underlayer circuit conductors adjacent to each other is filled with a semi-cured insulation resin; removing excessive insulation resin portions located above the underlayer circuit conductors by abrading the excessive resin portions; making a height of each of the underlayer circuit conductors lower than that of the insulation resin which fills each of the spaces between the adjacent underlayer circuit conductors, by use of soft etching technique; locating above the underlayer circuit conductors and on the insulation resin another semi-cured insulation resin film containing fillers; and pressurizing, heating and curing said another insulation resin film to thereby form a layer-insulation resin layer containing the fillers.

9. A mounting substrate having a printed wiring board on which electronic parts are mounted, the printed wiring board comprising circuit conductors, an insulation resin layer containing fillers which resin layer is located on the circuit conductors, and insulation resin portions which fill spaces each defined between the circuit conductors adjacent to each other and each of which resin portions has a height higher than the height of each of the circuit conductors.

10. An electronic device comprising a mounting substrate according to claim 9.
